(19) United States
(12) Patent Application Publication
(10) Pub. No.: US 2007/0076500 A1
(43) Pub. Date: Apr. 5, 2007

(54) Semiconductor memory device

(75) Inventors: Jae-Hyuk Im, Kyoungki-do (KR); Chang-Ho Do, Kyoungki-do (KR)

Correspondence Address: MCDERMOTT WILL & EMERY LLP, 600 13TH STREET, N.W., WASHINGTON, DC, 20005-3096, US

(73) Assignee: HYNIX SEMICONDUCTOR INC.

(21) Appl. No.: 11/528,532

(22) Filed: Sep. 28, 2006

(30) Foreign Application Priority Data
Sep. 28, 2005 (KR) 2005-0090856
May 31, 2006 (KR) 2006-0049138

(51) Int. Cl. G11C 7/02

(52) U.S. Cl. 365/208

(57) ABSTRACT

A semiconductor memory device is capable of resolving a problem of operational efficiency difference that can occur due to a loading difference on a supplying line while receiving a driving voltage of a unit bit line sense amplifier supplied from a certain part. The memory device includes a plurality of unit bit line sense amplifiers in a BLSA region, a pull-up power line and a pull-down power line used as power lines of the plurality of unit bit line sense amplifiers, a plurality of normal drivers connected to the pull-up power line at regular intervals in the BLSA region, and a plurality of over drivers connected to the pull-up power line at regular intervals in the BLSA region.

### FIELD OF THE INVENTION

The present invention relates to semiconductor design technologies, and more particularly, to a bit line sense amplifier array for use-in a semiconductor memory device.

### DESCRIPTION OF RELATED ART

In a semiconductor memory device, there is a current trend to reduce power supply voltage due to continuous scaling down of line width and cell size. Hence, a need has existed for design technology to meet the performance required for low voltage environments.

Most of semiconductor memory devices incorporate in a chip an internal voltage generation circuit that accepts an external voltage (power supply voltage) and generates an internal voltage. The memory devices allow the internal voltage generation circuits themselves to supply voltages required for operating circuits within the chip. Among them, in a memory device using a bit line sense amplifier, such as a Dynamic Random Access Memory (DRAM), a core voltage VCORE is employed to sense cell data.

As the core voltage that is used for the DRAM operating voltage becomes low, there may be difficulty in amplifying a plurality of cell data for a short time.

To solve such a problem, a bit line sense amplifier over driving method has been adopted for driving a pull-up power line of a bit line sense amplifier with a voltage (generally, power supply voltage VDD) higher than a core voltage VCORE for a prescribed time at an initial operation of the bit line sense amplifier, that is, after charge sharing between a memory cell and a bit line.

Hereinafter, a conventional semiconductor memory device adopting such an over driving method will be described.

FIG. 1 is a plan view of a conventional semiconductor memory device employing an over driving method.

Referring to FIG. 1, the conventional semiconductor memory device is divided into a cell area and a sub-hall area among many areas. The cell area is typically a cell array including a Word Line (WL) and a Bit Line (BL). And, the sub-hall area is typically a bit line sense amplifier driver that drives a bit line sense amplifier array having a Sub WL Driver (SWD) for driving the WL and a plurality of unit bit line sense amplifiers for sensing and amplifying data carried on the BL, and pull-up and pull-down power lines of the bit line sense amplifiers.

FIG. 2 is a circuit diagram of the bit line sense amplifier array depicted in FIG. 1.

Referring to FIG. 2, the bit line sense amplifier array is provided with a plurality of unit bit line sense amplifiers 201 and 203. In fact, there are a plurality of unit bit line sense amplifiers, but only two unit bit sense amplifiers are illustrated for convenience of explanation. In addition, bit line precharge portions 205 and 207 are further arranged to correspond to the unit bit line sense amplifiers 201 and 203 and precharge bit lines.

Further, in order to control the bit line sense amplifier array, there are prepared in the sub-hall area a normal driver 213, an over driver 211 and a pull-down driver 215 for driving power lines RTO and SB of the unit bit line sense amplifiers 201 and 203 by using the core voltage VCORE (normal driving voltage), the power supply voltage VDD (over driving voltage) and a ground voltage VSS. In FIG. 2, reference numeral 209 denotes a power line precharge portion for precharging the power lines RTO and SB of the unit bit line sense amplifiers 201 and 203.

More specifically, the normal driver 213 is driven by a normal driving signal SAP2, the over driver 211 is driven by an over driving signal SAP1, and the pull-down driver 215 is driven by a pull-down driving signal SAN.

The unit bit line sense amplifiers 201 and 203 perform sensing operations by commonly using the pull-up power line RTO. These amplifiers conduct the over driving operation during a certain initial interval of a sensing operation interval and thereafter the normal driving operation, thereby improving sensing efficiency.

In this process, however, the device for controlling the over driving operation is provided in the sub-hall area and shares its output (the normal driving voltage or over driving voltage). Therefore, the unit bit line sense amplifiers, which are relatively far from the sub-hall area having the over driver 211 and the normal driver 213, perform the over driving operation and normal driving operation only with a voltage decreased by loading of their power lines. Thus, there may be differences between sensing speeds and sensing efficiencies.

In addition, since the common node pull-up power line RTO is a sharing node between the plurality of unit bit line sense amplifiers 201 and 203 and thus weak in a mesh shape, there is a voltage drop resulting from power consumption in connecting the pull-up power line RTO and the power supply voltage VDD through the over driver 211 that generally utilizes a PMOS transistor for low power use.

### SUMMARY OF THE INVENTION

It is, therefore, an object of the present invention to provide a semiconductor memory device which receives a driving voltage of unit bit line sense amplifier supplied from any part therein but is capable of resolving an operational efficiency difference that occurs from a loading difference on a supply line.

Another object of the present invention is to provide a semiconductor memory device allowing a plurality of unit bit line sense amplifiers to have the same over driving operation efficiency and normal driving operation efficiency.

Still another object of the present invention is to provide a semiconductor memory device capable of solving a voltage drop problem by pull-up power lines (over driver and normal driver) that are weak in a mesh shape.

In accordance with an aspect of the present invention, there is provided a semiconductor memory device, including a plurality of unit bit line sense amplifiers in a BLSA region, a pull-up power line and a pull-down power line used as power lines of the plurality of unit bit line sense amplifiers, a plurality of normal drivers connected to the pull-up power line at regular intervals in the BLSA region, and a plurality of over drivers connected to the pull-up power line at regular intervals in the BLSA region.

In accordance with a further aspect of the present invention, there is provided a semiconductor memory device, including a cell region including a plurality of unit cell, a BLSA region including a plurality of bit line sense amplifiers, and a sub region including plural driving means, wherein the BLSA region includes a plurality of normal drivers for supplying a first operation voltage to the plurality of bit line sense amplifiers and a plurality of over drivers for supplying a second operation voltage to the plurality of bit line sense amplifiers.

### BRIEF DESCRIPTION OF THE DRAWINGS

The above and other objects and features of the instant invention will become apparent from the following description of preferred embodiments taken in conjunction with the accompanying drawings, in which:

FIG. 1 is a plan view of a conventional semiconductor memory device;

FIG. 2 is a circuit diagram of the bit line sense amplifier array shown in FIG. 1;

FIG. 3 is diagram of a bit line sense amplifier array in accordance with a preferred embodiment of the present invention;

FIG. 4 is a detailed circuit diagram of the bit line sense amplifier array shown in FIG. 3;

FIG. 5 is a diagram of a circuit that implements the over drivers and the normal drivers implemented with PMOS transistors in FIG. 4 with NMOS transistors; and

FIGS. 6A and 6B are diagrams of circuits that have the power line precharge portion in the X-hall area.

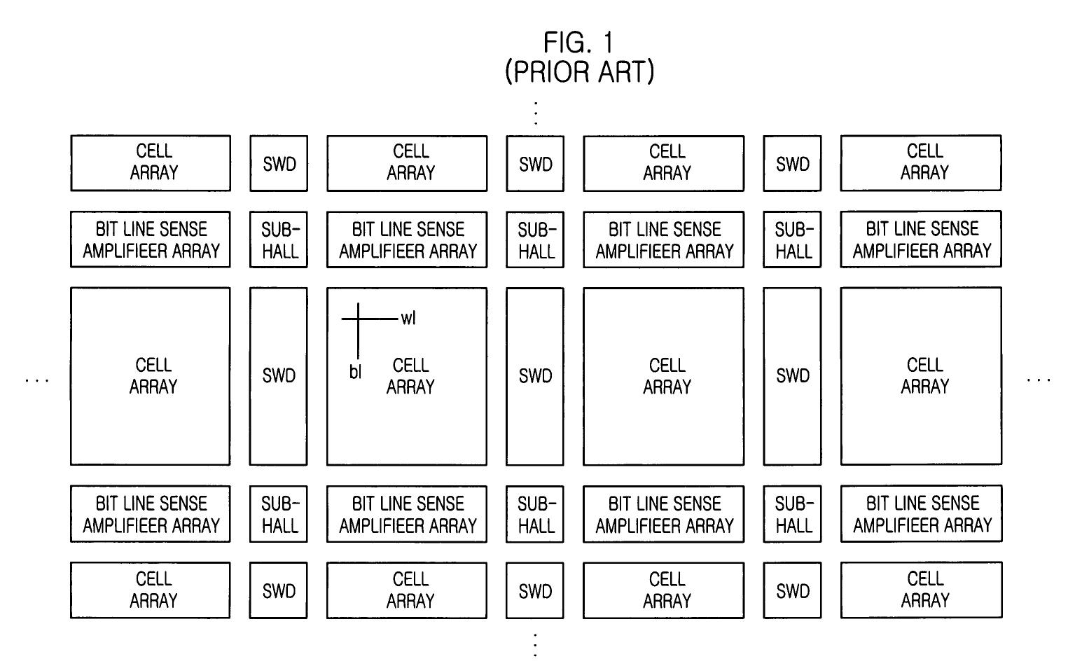

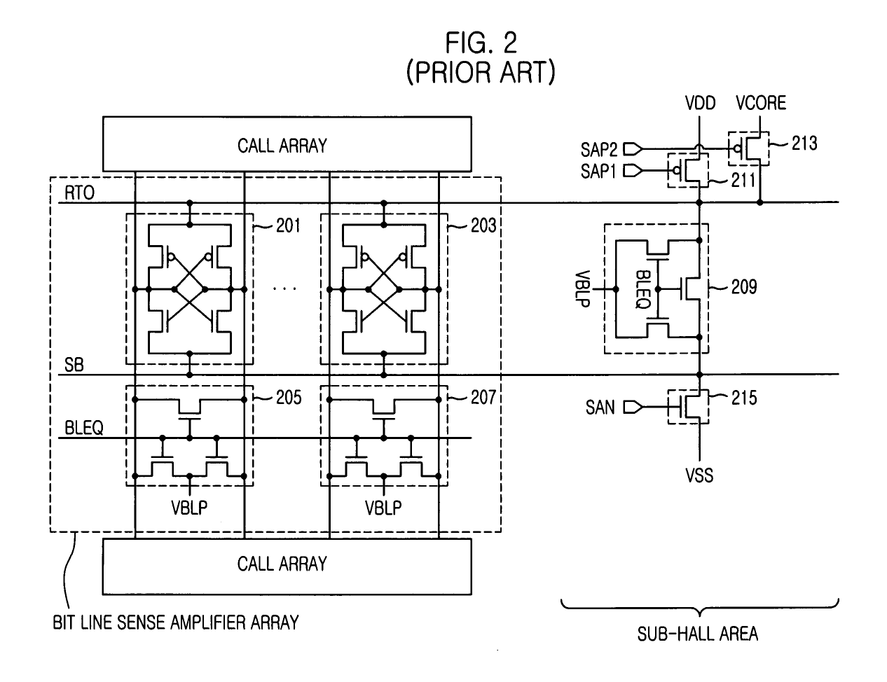

### DETAILED DESCRIPTION OF THE INVENTION

Hereinafter, preferred embodiments of the present invention will be set forth in detail with reference to the accompanying drawings to the extent that the invention can be readily carried out by those in the art to which the invention pertains.

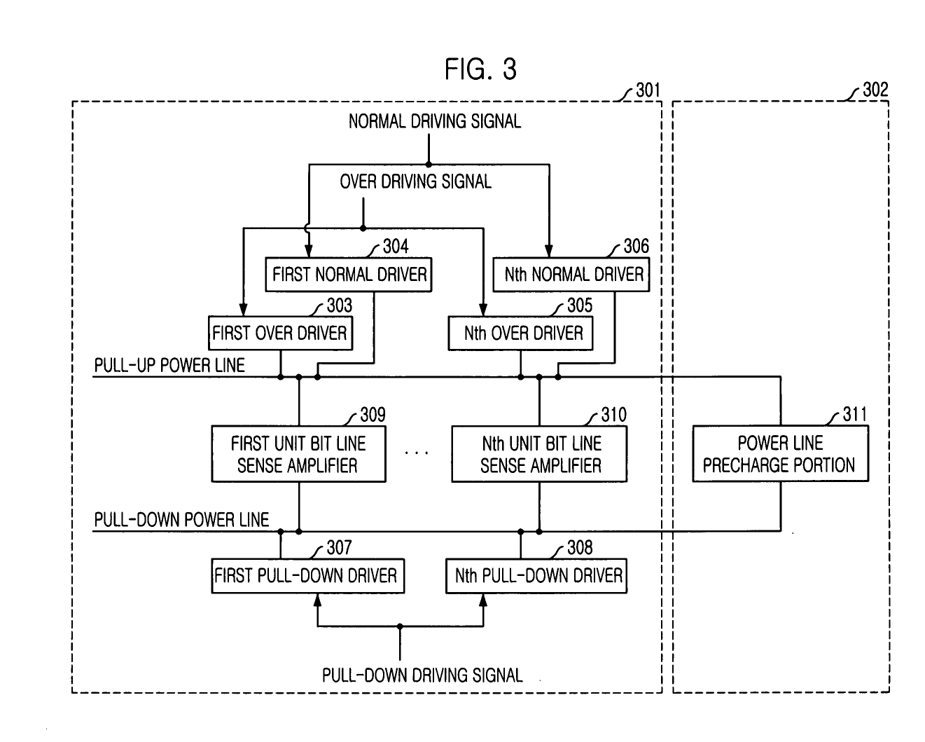

FIG. 3 is a diagram of a bit line sense amplifier array in accordance with a preferred embodiment of the present invention.

Referring to FIG. 3, the bit line sense amplifier array 301 includes a plurality of unit bit line sense amplifiers 309 and 310, a plurality of over drivers 303 and 305, a plurality of normal drivers 304 and 306, and a plurality of pull-down drivers 307 and 308 that are configured to correspond to the over drivers 303 and 305 and the normal drivers 304 and 306. In fact, there are provided a plurality (or N-number) of unit bit sense amplifiers, but only the two bit line sense amplifiers prepared at both ends are illustrated for convenience of explanation. The location and number of each of the over drivers 303 and 305, the normal drivers 304 and 306, and the pull-down drivers 307 and 308 may be arranged to correspond to those of the unit bit line sense amplifiers 309 and 310. That is, provided in the first unit bit line sense amplifier 309 are the first over driver 303 for over driving operation, the first normal driver 304 for normal driving operation, and the first pull-down driver 307 that are configured to correspond to the first over driver 303 and the first normal driver 304.

Further, the first over driver 303, the first normal driver 304 and the first pull-down driver 307 may be arranged individually in the first unit bit line sense amplifier 309. They may be also partially arranged within a range for which an efficiency difference does not occur due to loading difference of power line in transfer of over driving voltage (power supply voltage) and normal driving voltage (core voltage) for over driving and normal driving operations at far distance from the over driver 303 and the normal driver 304.

The normal drivers 304 and 306 are driven by a normal driving signal, the over drivers 303 and 305 are driven by an over driving signal, and the pull-down drivers 307 and 308 are driven by a pull-down driving signal.

In order to control the bit line sense amplifier array 301 as above, there is provided in a sub-hall area 302 a power line precharge portion 311 for precharging a pull-up power line and a pull-down power line which are power lines of the array 301.

The following is a detailed explanation of the concept of the present invention as discussed above.

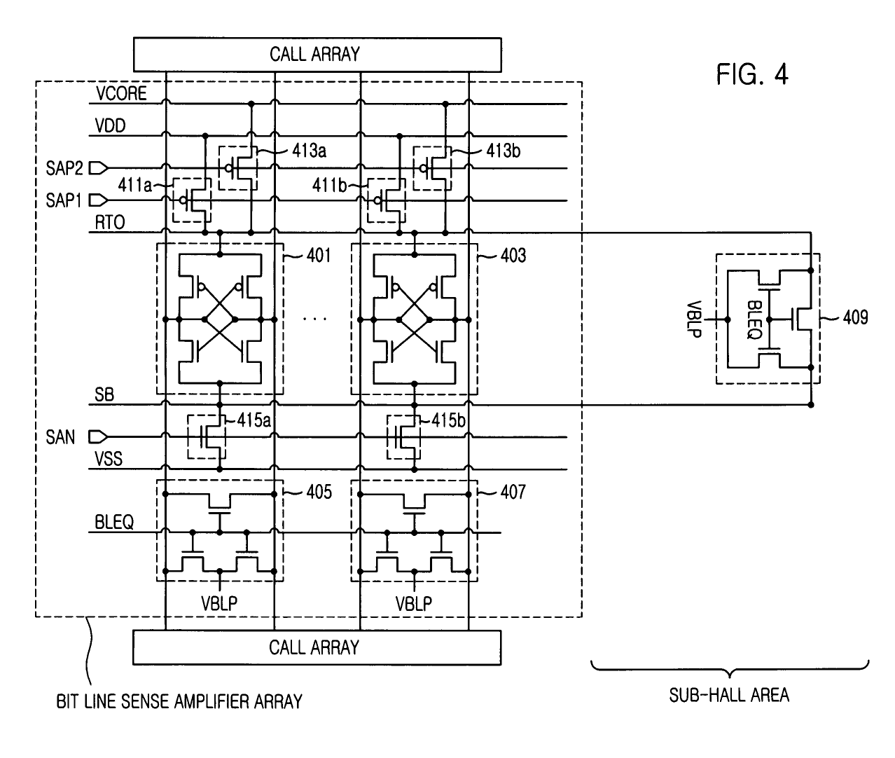

FIG. 4 is a detailed circuit diagram of the bit line sense amplifier array shown in FIG. 3.

With reference to FIG. 4, the bit line sense amplifier array is composed of a plurality of unit bit line sense amplifiers 401 and 403, a plurality of over drivers 411a and 411b, a plurality of normal drivers 413a and 413b, and a plurality of pull-down drivers 415a and 415b. In addition, bit line precharge portions 405 and 407 are further arranged to correspond to the unit bit line sense amplifiers 401 and 403 and to precharge bit lines.

As in FIG. 3, the location and number of each of the over drivers 411a and 411b, the normal drivers 413a and 413b, and the pull-down drivers 415a and 415b may be arranged to correspond to those of the unit bit line senses amplifiers 401 and 403. Further, the over driver 411a, the normal driver 413a and the pull-down driver 415a may be provided individually in the unit bit line sense amplifier 401. They may be also partially provided within the range that an efficiency difference does not occur due to loading difference of power line in transfer of over driving voltage (power supply voltage) and normal driving voltage (core voltage) for over driving and normal driving operations at far distance from the over driver 411a and the normal driver 413a.

To control the bit line sense amplifier array as above, there is prepared in the sub-hall area a power line precharge portion 409 for precharging power lines RTO and SB of the unit bit line sense amplifiers 401 and 403.

The normal drivers 413a and 413b are driven by a normal driving signal SAP2, the over drivers 411a and 411b are driven by an over driving signal SAP1, and the pull-down drivers 415a and 415b are driven by a pull-down driving signal SAN.

Further, each of the over drivers 411a and 411b and the normal drivers 413a and 413b may be implemented with a PMOS transistor, and each of the pull-down drivers 415a and 415b may be implemented with an NMOS transistor. This is made by considering the characteristics between a gate input and a threshold voltage of each transistor.

In the configuration, the present invention is provided with all or part of the over drivers 411a and 411b, the normal drivers 413a and 413b and the pull-down drivers 415a and 415b to correspond to the location and number of the unit bit line sense amplifiers 401 and 403, while the prior art has the single over driver on one side of the unit bit line sense amplifiers 401 and 403.

In succession, an operation of the bit line sense amplifier array will be described below in detail.

Data is first carried in the bit lines when they share charge with the memory cell, and the unit bit line sense amplifiers 401 and 403 are operated to amplify the data. At this time, the amplification operation of the unit bit line sense amplifiers 401 and 403 is made in such a way that the over driving signal SAP1 is activated for over driving operation during an initial operation interval to drive the over drivers 411a and 411b and the normal driving signal SAP2 is activated for normal driving operation during the subsequent intervals to drive the normal drivers 413a and 413b.

Further, the present invention can prevent a malfunctioning of the unit bit line sense amplifiers 401 and 403 since it includes the plurality of over drivers 411a and 411b and normal drivers 413a and 413b even when any of the over drivers 411a and 411b and any of the normal drivers 413a and 413b are not operated by issuance of any problem therein.

Also, the present invention solves the existing voltage drop problem that can occur due to a weakness of the pull-up power line RTO driven by a single power source, that is, power supply voltage VDD, in the mesh shape. This is accomplished by allowing the pull-up power line RTO to use a plurality of power supply voltages by the plurality of the over drivers 411a and 411b. The normal drivers 413a and 413b are used in the same manner.

The present invention is not limited to the embodiment as described above and the accompanying drawings and it will be apparent to those skilled in the art that various changes and modifications may be made without departing from the technical aspect of the invention.

For instance, it should be noted that the logic gates and transistors illustrated in the preferred embodiment as mentioned above may be implemented with different gate types and arrangements based on polarities of input and output signals used therein.

Further, although the present invention is illustrated with respect to the case where the over drivers 411a and 411b and the normal drivers 413a and 413b are implemented with PMOS transistors, and the pull-down drivers 415a and 415b that are configured to correspond to the over drivers 411a and 411b and the normal drivers 413a and 413b are implemented with NMOS transistors in the above embodiment, this illustration is but one implementation example.

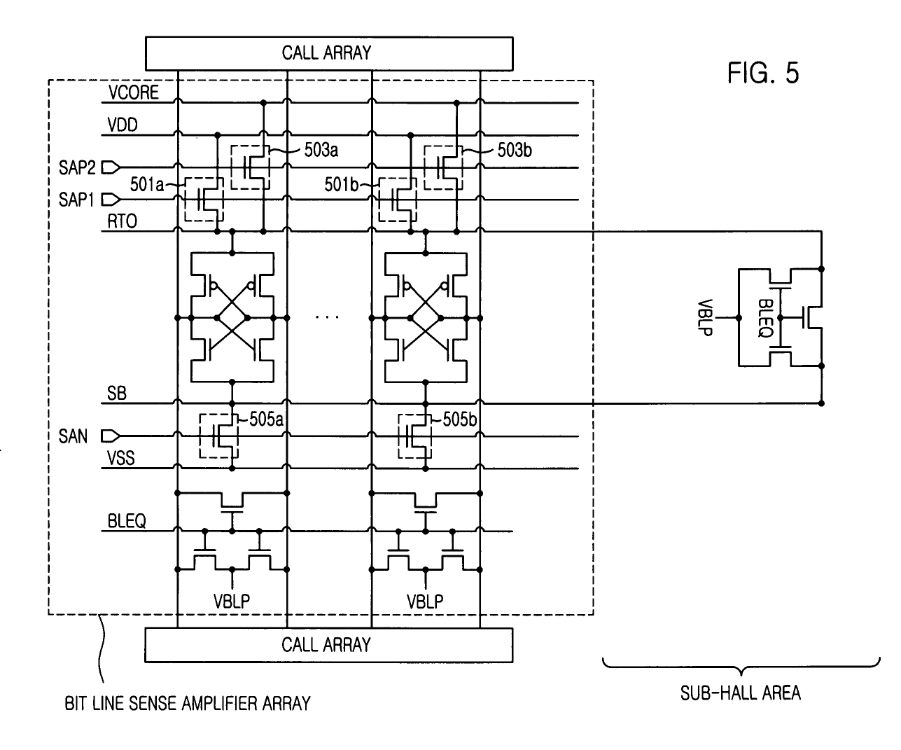

Referring to FIG. 5, there is shown an example that implements the over drivers 501a and 501b and the normal drivers 503a and 503b implemented with PMOS transistors in FIG. 4 with NMOS transistors.

As such, in case where the over drivers 501a and 501b and the normal drivers 503a and 503b are implemented with NMOS transistors, the over drivers 501a and 501b should be driven by a higher voltage than the power supply voltage VDD by at least a threshold voltage and the normal drivers 503a and 503b should be driven by a higher voltage than the core voltage VCORE by at least a threshold voltage.

As mentioned above, when the NMOS transistors are used, the power consumption of the semiconductor memory device is increased. In general, however, the use of the NMOS transistors can decrease the size of the semiconductor memory device because they are implemented by an area smaller than that of PMOS transistors. The result is obtained under the assumption that the PMOS transistors in which electrons are minority carriers have a small number of electrons existing per unit area compared to the NMOS transistors and thus acquire a same driving current.

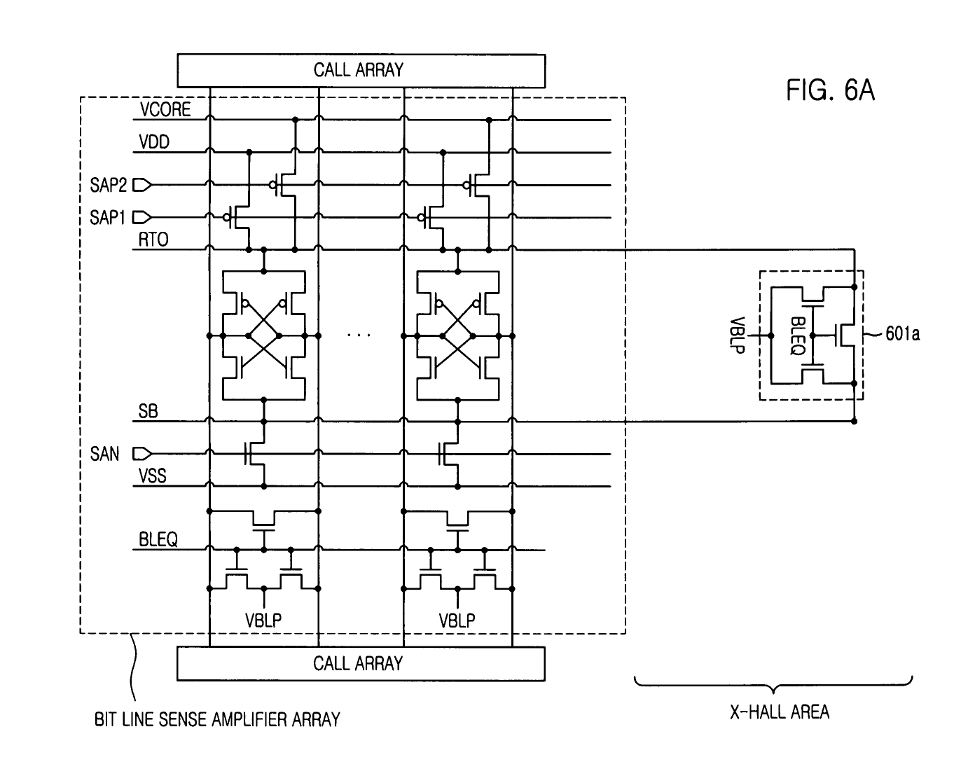

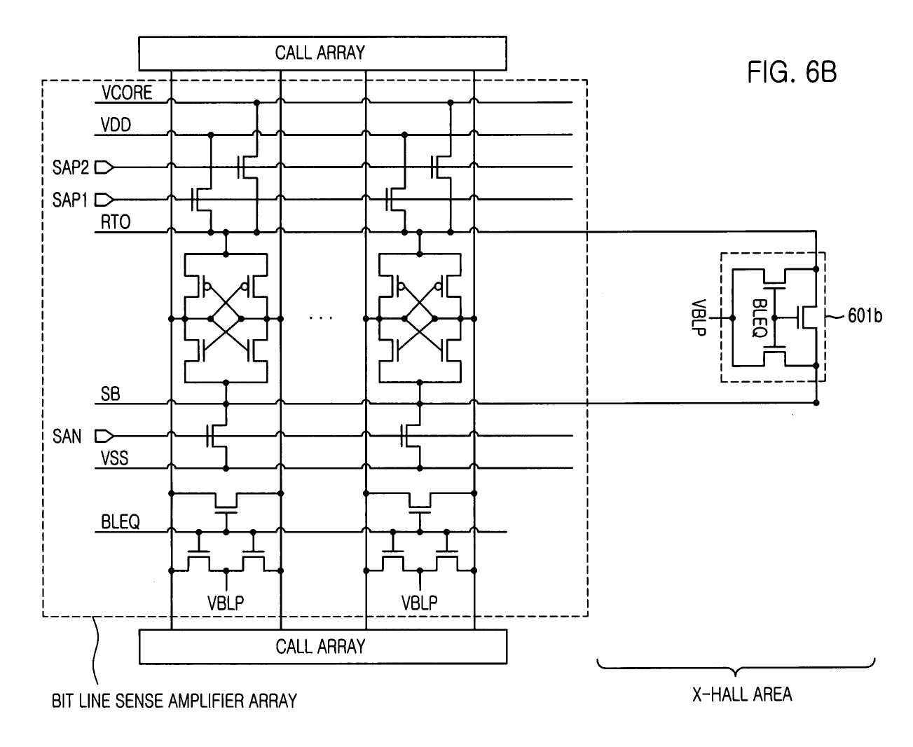

FIGS. 6A and 6B are circuit diagrams showing examples that have the power line precharge portion in an X-hall area.

The X-hall area herein is an area that corresponds to a row address pass and has an X decoder and a main word line driver, wherein one X-hall area is arranged per bank.

That is, by arranging the power line precharge portion for precharging the power line of the unit bit line sense amplifier in the X-hall area as in FIGS. 6A and 6B, it is possible to precharge the power lines of the plurality of unit bit line sense amplifiers in which one power line precharge portion is contained in one bank.

Accordingly, a space restriction problem can be resolved by arranging one power line precharge portion per unit bit line sense amplifier.

As set forth above, the present invention allows the unit bit line sense amplifiers to perform stable over driving and normal driving operations by preventing occurrence of over driving operation efficiency difference and normal driving operation efficiency difference therebetween, and also can improve the speed of the semiconductor memory device.

Further, the present invention can prevent a malfunctioning of the unit bit line sense amplifiers since it includes the plurality of over drivers and normal drivers, even when any of the over drivers and any of the normal drivers are not operated.

Moreover, the present invention can solve the voltage drop problem that occurs due to the pull-up power line that is weak in a mesh shape, thereby achieving reduction in power consumption.

The present invention can accomplish reduction in area and power of the semiconductor memory device by implementing the over drivers and the normal drivers with PMOS or NMOS transistors.

The present application contains subject matter related to the Korean patent applications Nos. KR 10-2005-0090856 and KR 10-2006-0049138, filed in the Korean Patent Office on Sep. 28, 2005 and on May 31, 2006, respectively, the entire contents of which being incorporated herein by references.

While the present invention has been described with respect to certain specific embodiments, it will be apparent to those skilled in the art that various changes and modifications may be made without departing from the spirit and scope of the invention as defined in the following claims.

What is claimed is:

1. A semiconductor memory device, comprising:
a plurality of unit bit line sense amplifiers in a BLSA region;
a pull-up power line and a pull-down power line used as power lines of the plurality of unit bit line sense amplifiers;
a plurality of normal drivers connected to the pull-up power line at regular intervals in the BLSA region; and
a plurality of over drivers connected to the pull-up power line at regular intervals in the BLSA region.

2. The semiconductor memory device as recited in claim 1, further comprising a plurality of pull-down drivers partially connected to the pull-down power line at regular intervals.

3. The semiconductor memory device as recited in claim 1, further comprising a power line precharge region that is arranged to correspond to a bit line sense amplifier array that is the plurality of unit bit line sense amplifiers, and precharges the pull-up power line.

4. The semiconductor memory device as recited in claim 2, wherein the number of the over drivers, the normal drivers and the pull-down drivers corresponds to that of the plurality of unit bit line sense amplifiers.

5. The semiconductor memory device as recited in claim 1, wherein each of the over drivers is an NMOS transistor or PMOS transistor.

6. The semiconductor memory device as recited in claim 1, wherein each of the normal drivers is an NMOS transistor or PMOS transistor.

7. The semiconductor memory device as recited in claim 5, wherein if each of the over drivers is an NMOS transistor, a driving voltage is a voltage higher than a power supply voltage by a threshold voltage.

8. The semiconductor memory device as recited in claim 6, wherein if each of the normal drivers is an NMOS transistor, a driving voltage is a voltage higher than a core voltage by a threshold voltage.

9. The semiconductor memory device as recited in claim 3, wherein the power line precharge region is arranged to correspond to a bank.

10. A semiconductor memory device, comprising:
a cell region including a plurality of unit cell;
a BLSA region including a plurality of bit line sense amplifiers; and
a sub region including plural driving means,
wherein the BLSA region includes:
a plurality of normal drivers for supplying a first operation voltage to the plurality of bit line sense amplifiers; and
a plurality of over drivers for supplying a second operation voltage to the plurality of bit line sense amplifiers.

11. The semiconductor memory device as recited in claim 10, wherein the normal driver includes two drivers, each for supplying the first operation voltage to each of the pull-up power line and the pull-down power line.

12. The semiconductor memory device as recited in claim 11, wherein the first operation voltage includes a core voltage and a ground voltage.

13. The semiconductor memory device as recited in claim 12, wherein the over driver includes a driver for supplying the second operation voltage to the pull-up power line, wherein a level of the second operation voltage is higher than or equivalent to that of the core voltage.

14. The semiconductor memory device as recited in claim 10, further comprising a power line precharge region that is arranged to correspond to a bit line sense amplifier array that is the plurality of unit bit line sense amplifiers, and precharges the pull-up power line.

15. The semiconductor memory device as recited in claim 14, wherein the power line precharge region is arranged to correspond to a bank.

16. The semiconductor memory device as recited in claim 11, wherein the number of the over drivers, the normal drivers and the pull-down drivers corresponds to that of the plurality of unit bit line sense amplifiers.

17. The semiconductor memory device as recited in claim 10, wherein each of the over drivers and normal drivers is an NMOS transistor or PMOS transistor.

18. The semiconductor memory device as recited in claim 17, wherein the NMOS transistor is coupled to a voltage having a higher threshold voltage level than a power supply voltage or a lower threshold voltage level than a ground voltage.

19. The semiconductor memory device as recited in claim 17, wherein the PMOS transistor is coupled to a voltage having a higher threshold voltage level than a power supply voltage.
